(19) United States
(12) Patent Application Publication
(10) Pub. No.: US 2024/0112927 A1
(43) Pub. Date: Apr. 4, 2024

(54) ETCHING METHOD AND PLASMA PROCESSING APPARATUS

(71) Applicant: Tokyo Electron Limited, Tokyo (JP)

(72) Inventors: Fumiya TAKATA, Miyagi (JP); Wataru TOGASHI, Hillsboro, OR (US); Kota OIKAWA, Miyagi (JP)

(73) Assignee: Tokyo Electron Limited, Tokyo (JP)

(21) Appl. No.: 18/376,050

(22) Filed: Oct. 3, 2023

(30) Foreign Application Priority Data
Oct. 4, 2022 (JP) 2022-160398

(51) Int. Cl. H01L 21/67; H01L 21/3065

(52) U.S. Cl. CPC H01L 21/67069; H01L 21/3065

(57) ABSTRACT

In one embodiment, an etching method includes (a) preparing a substrate having a first region including a first material that contains silicon, and a second region including a second material different from the first material, and (b) etching the first region by plasma generated from a processing gas containing a carbon- and fluorine-containing gas, a nitrogen-containing gas, and a metal halide gas. In (b), a flow rate of the metal halide gas is lower than a flow rate of the carbon- and fluorine-containing gas and a flow rate of the nitrogen-containing gas.

### CROSS-REFERENCE TO RELATED APPLICATION

This application is based on and claims priority from Japanese Patent Application No. 2022-160398, filed on Oct. 4, 2022, with the Japan Patent Office, the disclosure of which is incorporated herein in its entirety by reference.

### TECHNICAL FIELD

An embodiment of the present disclosure relates to an etching method and a plasma processing apparatus.

### BACKGROUND

Japanese Patent Laid-Open Publication No. H09-050984 discloses a method of etching an insulating film by using plasma. In the method, etching is performed while a conductive layer is being formed on the surface of an insulating film. In the etching, plasma generated from a mixed gas of WF₆ and C₄F₈ is used.

### SUMMARY

In one embodiment, an etching method includes (a) preparing a substrate having a first region including a first material that contains silicon, and a second region including a second material different from the first material, and (b) etching the first region by plasma generated from a processing gas containing a carbon- and fluorine-containing gas, a nitrogen-containing gas, and a metal halide gas. In (b), a flow rate of the metal halide gas is lower than a flow rate of the carbon- and fluorine-containing gas and a flow rate of the nitrogen-containing gas.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view schematically illustrating a plasma processing apparatus according to one embodiment.

FIG. 2 is a view schematically illustrating a plasma processing apparatus according to one embodiment.

FIG. 3 is a flowchart of an etching method according to one embodiment.

FIG. 4 is a cross-sectional view of a substrate as an example to which the method of FIG. 3 may be applied.

FIG. 5 is a cross-sectional view illustrating one process of the etching method according to one embodiment.

FIG. 6 is a view illustrating an example of a TEM image of a cross section of a substrate obtained by executing the etching method in a first experiment.

FIG. 7 is a view illustrating an example of a TEM image of a cross section of a substrate obtained by executing the etching method in a second experiment.

FIG. 8 is a graph illustrating an example of the relationship between the flow rate of a hydrogen gas and the etching amount or the etching selectivity.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, various embodiments will be described in detail with reference to drawings. In the drawings, it is assumed that the same or equivalent parts are denoted by the same reference numerals.

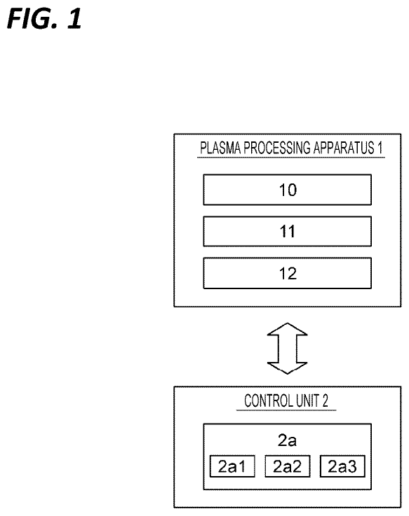

FIG. 1 is a view illustrating a configuration example of a plasma processing system. In one embodiment, the plasma processing system includes a plasma processing apparatus 1 and a control unit 2. The plasma processing system is an example of a substrate processing system, and the plasma processing apparatus 1 is an example of a substrate processing apparatus. The plasma processing apparatus 1 includes a plasma processing chamber 10, a substrate support unit 11 and a plasma generation unit 12. The plasma processing chamber 10 has a plasma processing space. The plasma processing chamber 10 has at least one gas supply port for supplying at least one processing gas to the plasma processing space, and at least one gas outlet for exhausting gas from the plasma processing space. The gas supply port is connected to a gas supply 20 to be described below, and the gas outlet is connected to an exhaust system 40 to be descried below. The substrate support unit 11 is disposed within the plasma processing space, and has a substrate supporting surface for supporting a substrate.

The plasma generation unit 12 is configured to generate plasma from at least one processing gas supplied into the plasma processing space. The plasma formed in the plasma processing space may be, for example, capacitively coupled plasma (CCP), inductively coupled plasma (ICP), electron-cyclotron-resonance plasma (ECR plasma), helicon wave-excited plasma (HWP), or surface wave plasma (SWP). Various types of plasma generation units, including an alternating current (AC) plasma generation unit and a direct current (DC) plasma generation unit, may be used. In one embodiment, the AC signal (AC power) used in the AC plasma generation unit has a frequency within a range of 100 kHz to 10 GHz. Therefore, AC signals include radio-frequency (RF) signals and microwave signals. In one embodiment, the RF signal has a frequency within the range of 100 kHz to 150 MHz.

The control unit 2 processes computer-executable instructions that cause the plasma processing apparatus 1 to execute various steps described in the present disclosure. The control unit 2 may be configured to control each element of the plasma processing apparatus 1 so as to execute various steps described herein. In one embodiment, a part or all of the control unit 2 may be included in the plasma processing apparatus 1. The control unit 2 may include a processing unit 2a1, a storage unit 2a2 and a communication interface 2a3. The control unit 2 is realized by, for example, a computer 2a. The processing unit 2a1 may be configured to read a program from the storage unit 2a2, and to execute the read program so as to perform various control operations. This program may be stored in the storage unit 2a2 in advance, or may be acquired via a medium if necessary. The acquired program is stored in the storage unit 2a2, and is read from the storage 2a2 unit by the processing unit 2a1 and then is executed. The medium may be various storage media readable by the computer 2a or may be a communication line connected to the communication interface 2a3. The processing unit 2a1 may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

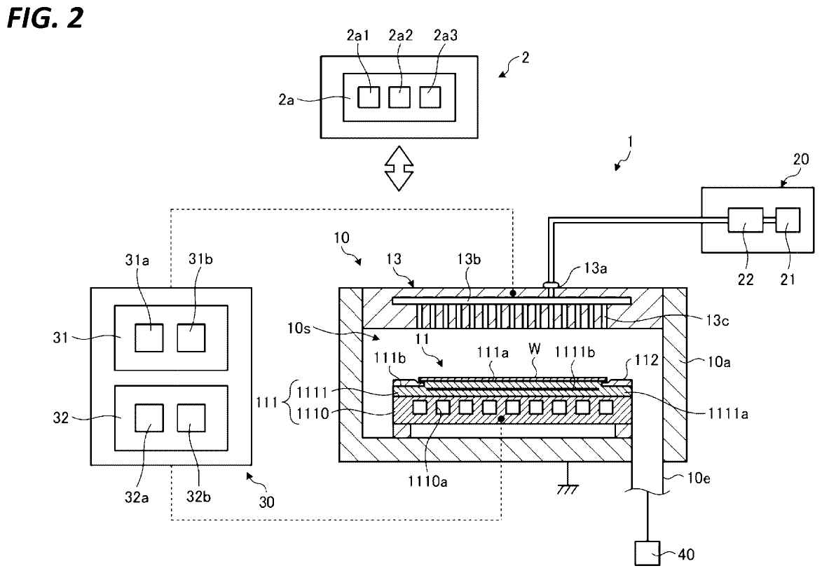

Hereinafter, descriptions will be made on a configuration example of a capacitively coupled plasma processing apparatus as an example of the plasma processing apparatus 1. FIG. 2 is a view illustrating a configuration example of a capacitively coupled plasma processing apparatus.

The capacitively coupled plasma processing apparatus 1 includes the plasma processing chamber 10, the gas supply 20, a power supply 30 and the exhaust system 40. The plasma processing apparatus 1 also includes the substrate support unit 11 and a gas introduction section. The gas introduction section is configured to introduce at least one processing gas into the plasma processing chamber 10. The gas introduction section includes a shower head 13. The substrate support unit 11 is disposed within the plasma processing chamber 10. The shower head 13 is disposed above the substrate support unit 11. In one embodiment, the shower head 13 constitutes at least a part of the ceiling of the plasma processing chamber 10. The plasma processing chamber 10 has a plasma processing space 10s defined by the shower head 13, a side wall 10a of the plasma processing chamber 10, and the substrate support unit 11. The plasma processing chamber 10 is grounded. The shower head 13 and the substrate support unit 11 are electrically insulated from the housing of the plasma processing chamber 10.

The substrate support unit 11 includes a main body 111 and a ring assembly 112. The main body 111 has a central region 111a for supporting a substrate W, and an annular region 111b for supporting the ring assembly 112. A wafer is an example of the substrate W. In plan view, the annular region 111b of the main body 111 surrounds the central region 111a of the main body 111. The substrate W is disposed on the central region 111a of the main body 111, and the ring assembly 112 is disposed on the annular region 111b of the main body 111 so as to surround the substrate W on the central region 111a of the main body 111. Therefore, the central region 111a is also called a substrate supporting surface for supporting the substrate W, and the annular region 111b is also called a ring supporting surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed within the ceramic member 1111a. The ceramic member 1111a has the central region 111a. In one embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power supply 31 and/or a DC power supply 32 to be described below may be disposed within the ceramic member 1111a. In this case, at least one RF/DC electrode functions as the lower electrode. If a bias RF signal and/or a DC signal to be described below is supplied to at least one RF/DC electrode, the RF/DC electrode is also called a bias electrode. The conductive member of the base 1110 and at least one RF/DC electrode may function as a plurality of lower electrodes. Further, the electrostatic electrode 1111b may function as the lower electrode. Therefore, the substrate support unit 11 includes at least one lower electrode.

The ring assembly 112 includes one or more annular members. In one embodiment, one or more annular members include one or more edge rings and at least one cover ring. The edge ring is made of a conductive material or an insulating material, and the cover ring is made of an insulating material.

The substrate support unit 11 may include a temperature control module configured to control at least one of the electrostatic chuck 1111, the ring assembly 112, and the substrate, to a target temperature. The temperature control module may include a heater, a heat transfer medium, and a flow path 1110a, or a combination thereof. A heat transfer fluid such as brine or gas flows through the flow path 1110a. In one embodiment, the flow path 1110a is formed within the base 1110, and one or more heaters are disposed within the ceramic member 1111a of the electrostatic chuck 1111. The substrate support unit 11 may include a heat transfer gas supply configured to supply a heat transfer gas to the gap between the back surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a is introduced into the plasma processing space 10s from the plurality of gas introduction ports 13c through the gas diffusion chamber 13b. The shower head 13 includes at least one upper electrode. In addition to the shower head 13, the gas introduction section may include one or more side gas injectors (SGIs) attached to one or more openings formed in the side wall 10a.

The gas supply unit 20 may include at least one gas source 21 and at least one flow controller 22. In one embodiment, the gas supply 20 is configured to supply at least one processing gas to the shower head 13, from each corresponding gas source 21 through each corresponding flow controller 22. Each flow controller 22 may include, for example, a mass flow controller or a pressure control-type flow controller. Further, the gas supply 20 may include at least one flow modulation device that modulates or pulses the flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. Accordingly, plasma is formed from at least one processing gas supplied to the plasma processing space 10s. Therefore, the RF power supply 31 may function as at least a part of the plasma generation unit 12. When a bias RF signal is supplied to at least one lower electrode, a bias potential is generated in the substrate W, and ion components in the formed plasma may be drawn into the substrate W.

In one embodiment, the RF power supply 31 includes a first RF generation unit 31a and a second RF generation unit 31b. The first RF generation unit 31a is coupled to at least one lower electrode and/or at least one upper electrode via at least one impedance matching circuit, and is configured to generate a source RF signal (source RF power) for plasma generation. In one embodiment, the source RF signal has a frequency within a range of 10 MHz to 150 MHz. In one embodiment, the first RF generation unit 31a may be configured to generate source RF signals having different frequencies. One or more generated source RF signals are supplied to at least one lower electrode and/or at least one upper electrode.

The second RF generation unit 31b is coupled to at least one lower electrode via at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generation unit 31b may be configured to generate bias RF signals having different frequencies. One or more generated bias RF signals are supplied to at least one lower electrode. In various embodiments, at least one of the source RF signal and the bias RF signal may be pulsed.

The power supply 30 may include the DC power supply 32 coupled to the plasma processing chamber 10. The DC power supply 32 includes a first DC generation unit 32a and a second DC generation unit 32b. In one embodiment, the first DC generation unit 32a is connected to at least one lower electrode, and is configured to generate a first DC signal. The generated first DC signal is applied to at least one lower electrode. In one embodiment, the second DC generation unit 32b is connected to at least one upper electrode, and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulses may have a pulse waveform of a rectangle, a trapezoid, a triangle, or a combination thereof. In one embodiment, a waveform generation unit that generates a sequence of voltage pulses from DC signals is connected between the first DC generation unit 32a and at least one lower electrode. Therefore, the first DC generation unit 32a and the waveform generation unit constitute a voltage pulse generation unit. When the second DC generation unit 32b and the waveform generation unit constitute the voltage pulse generation unit, the voltage pulse generation unit is connected to at least one upper electrode. The voltage pulse may have a positive polarity or may have a negative polarity. The sequence of voltage pulses may include one or more positive voltage pulses and one or more negative voltage pulses within one period. The first and second DC generation units 32a and 32b may be provided in addition to the RF power supply 31, or the first DC generation unit 32a may be provided instead of the second RF generation unit 31b.

The exhaust system 40 may be connected to, for example, a gas outlet 10e provided at the bottom of the plasma processing chamber 10. The exhaust system 40 may include a pressure regulation valve and a vacuum pump. By the pressure regulation valve, the pressure within the plasma processing space 10s is adjusted. The vacuum pump may include a turbomolecular pump, a dry pump, or a combination thereof.

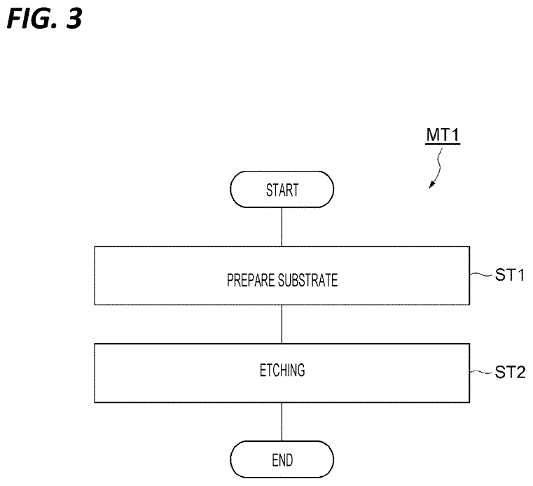

FIG. 3 is a flowchart of an etching method according to one embodiment. The etching method MT1 (hereinafter, referred to as a “method MT1”) illustrated in FIG. 3 may be executed by the plasma processing apparatus 1 of the embodiment. The method MT1 may be applied to the substrate W.

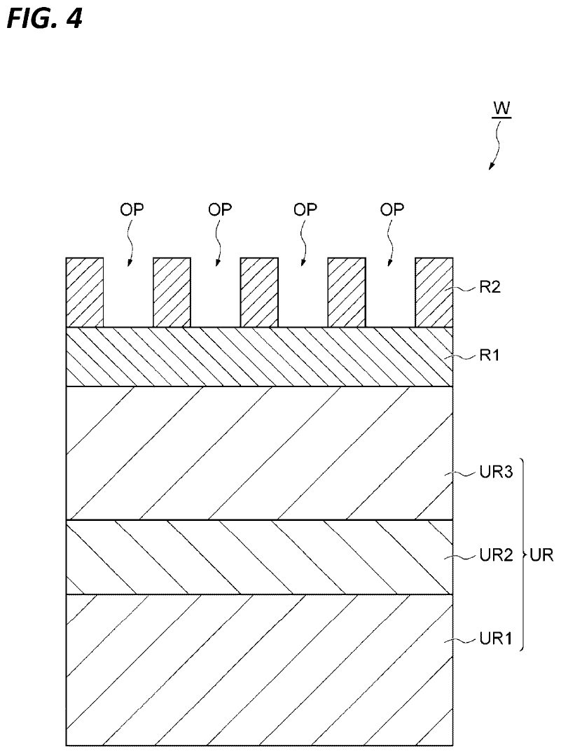

FIG. 4 is a cross-sectional view of the substrate as an example to which the method of FIG. 3 may be applied. As illustrated in FIG. 4, in one embodiment, the substrate W includes a first region R1 and a second region R2. The second region R2 may have at least one opening OP. The second region R2 may have a plurality of openings OP. The opening OP may have a hole pattern, or may have a line pattern.

The critical dimension (CD) of the opening OP may be 100 nm or less, 50 nm or less, or 30 nm or less. The second region R2 may be present on the first region R1. The substrate W may further include an underlayer region UR. The underlayer region UR may be present under the first region R1.

The first region R1 includes a first material containing silicon. The first region R1 may be a silicon oxide film. The first region R1 may be a spin on glass (SOG) film.

The second region R2 includes a second material different from the first material of the first region R1. The second region R2 may be a mask having the opening OP on the first region R1. The second region R2 may be a photoresist film. The second region R2 may be a photoresist film for EUV exposure.

The underlayer region UR may include a first underlayer region UR1, a second underlayer region UR2, and a third underlayer region UR3. The first underlayer region UR1, the second underlayer region UR2 and the third underlayer region UR3 are arranged in order. The third underlayer region UR3 is provided between the first region R1 and the second underlayer region UR2. The first underlayer region UR1, the second underlayer region UR2 and the third underlayer region UR3 may be stacked films.

The first underlayer region UR1 may contain silicon and nitrogen. The first underlayer region UR1 may contain silicon nitride (SiNₓ). The second underlayer region UR2 may contain silicon and oxygen. The second underlayer region UR2 may contain silicon oxide (SiOₓ). The third underlayer region UR3 may be a spin on carbon (SOC) film or may be a carbon-containing film.

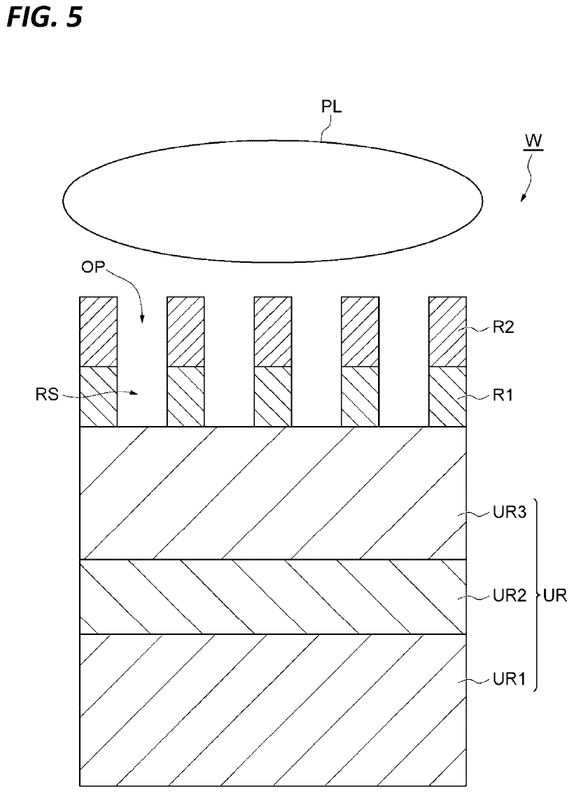

Hereinafter, the method MT1 will be described with reference to FIGS. 3 to 5, taking, as an example, a case where the method MT1 is applied to the substrate W by using the plasma processing apparatus 1 of the embodiment. FIG. 5 is a cross-sectional view illustrating one process of the etching method according to one embodiment. When the plasma processing apparatus 1 is used, the control unit 2 controls each unit of the plasma processing apparatus 1 so that the method MT1 may be executed in the plasma processing apparatus 1. In the method MT1, as illustrated in FIG. 2, the substrate W on the substrate support unit 11 disposed within the plasma processing chamber 10 is processed.

As illustrated in FIG. 3, the method MT1 may include step ST1 and step ST2. Step ST1 and step ST2 may be executed in order.

(Step ST1)

In step ST1, the substrate W illustrated in FIG. 4 is provided. The substrate W may be supported by the substrate support unit 11 within the plasma processing chamber 10.

(Step ST2)

In step ST2, as illustrated in FIG. 5, the first region R1 is etched with plasma PL generated from the processing gas. Accordingly, a recess RS corresponding to the opening OP of the second region R2 may be formed in the first region R1. The recess RS may be an opening.

The processing gas in step ST2 includes a carbon- and fluorine-containing gas, a nitrogen-containing gas, and a metal halide gas. The processing gas may further include a hydrogen-containing gas.

The carbon- and fluorine-containing gas may contain at least one of fluorocarbon (CₓF_{y}) gas and hydrofluorocarbon (CₓH_{y}F_{z}) gas. Examples of the fluorocarbon gas include CF₄ gas, C₃F₆ gas, C₃F₈ gas, C₄F₈ gas, and C₄F₆ gas. Examples of the hydrofluorocarbon gas include CH₂F₂ gas, CHF₃ gas, and CH₃F gas.

The nitrogen-containing gas may contain nitrogen (N₂) gas.

The metal halide gas may contain at least one metal of tungsten, titanium, molybdenum, vanadium, platinum, hafnium, niobium, tantalum, and rhenium. The metal halide gas may contain fluorine. The metal halide gas may contain at least one of tungsten hexafluoride (WF₆) gas, tungsten hexabromide (WBr₆) gas, tungsten hexachloride (WCl₆) gas, WF₅C₁ gas, titanium tetrachloride (TiCl₄) gas, molybdenum pentafluoride (MoF₅) gas, vanadium hexafluoride (VF₆) gas, platinum hexafluoride (PtF₆) gas, hafnium tetrafluoride (HfF₄) gas, and niobium pentafluoride (NbF₅) gas.

The hydrogen-containing gas may contain at least one of hydrogen (H₂) gas, monosilane (SiH₄) gas, and ammonia (NH₃) gas.

In step ST2, the flow rate of the metal halide gas is lower than the flow rate of the carbon- and fluorine-containing gas and the flow rate of the nitrogen-containing gas. The flow rate of the nitrogen-containing gas may be higher than the flow rate of the carbon- and fluorine-containing gas, or may be lower than the flow rate of the carbon- and fluorine-containing gas. The flow rate of the hydrogen-containing gas may be lower than the flow rate of the carbon- and fluorine-containing gas and the flow rate of the nitrogen-containing gas. The flow rate of the metal halide gas may be lower than the flow rate of the hydrogen-containing gas. The flow rate of the metal halide gas may be 20 sccm or less, 10 sccm or less, or 3 sccm or more. The flow rate of the hydrogen-containing gas may be 20 sccm or less.

In step ST2, the temperature of the substrate support unit 11 may be 10° C. or more or may be 30° C. or less.

After step ST2, the third underlayer region UR3 may be etched. After that, the second underlayer region UR2 may be etched.

According to the method MT1, it is possible to improve the etching selectivity of the first region R1 with respect to the second region R2. The mechanism is presumed as follows, but is not limited thereto. In step ST2, carbon-containing deposits and metal-containing deposits are formed on the second region R2, so that the etching amount of the second region R2 is reduced. The carbon-containing deposits originate from the carbon- and fluorine-containing gas. The metal-containing deposits originate from the metal halide gas. The metal-containing deposits may contain nitrogen. When the etching selectivity of the first region R1 with respect to the second region R2 is improved, the thickness of the second region R2 may be reduced.

By reducing the flow rate of the metal halide gas, it is possible to suppress the etching of the side wall of the recess RS formed in the first region R1. Accordingly, it is possible to suppress the shape abnormality (bowing) of the side wall of the recess RS. It is presumed that if excess halogen is contained in the metal halide gas, the side wall of the recess RS is excessively etched, but the mechanism is not limited thereto.

Furthermore, according to the method MT1, the verticality of the side wall of the recess RS formed in the first region R1 is improved. That is, the side wall of the recess RS is suppressed from being tapered. Therefore, it is possible to improve the dimensional uniformity at the bottom of the recess RS. The value (3σ) of a local CD uniformity (LCDU) is used as an index indicating the dimensional uniformity. It is presumed that the verticality of the side wall of the recess (RS) is improved by reducing the etching amount of the second region R2, but the mechanism is not limited thereto.

When the processing gas in step ST2 further contains a hydrogen-containing gas, it is possible to further improve the etching selectivity of the first region R1 with respect to the second region R2. The mechanism is presumed as follows, but is not limited thereto. In step ST2, more deposits are formed on the second region R2. For example, deposits containing carbon and hydrogen are formed on the second region R2. Otherwise, the metal halide gas is reduced by the hydrogen-containing gas, so that metal deposits are formed on the second region R2.

In step ST2, when the flow rate of the nitrogen-containing gas is lower than the flow rate of the carbon- and fluorine-containing gas, it is possible to reduce the amount of deposits formed on the second region R2. Therefore, it is possible to suppress the recess RS from being clogged with deposits.

Hereinafter, descriptions will be made on various experiments performed for evaluation of the method MT1. The experiments described below do not limit the present disclosure.

### First Experiment

In the first experiment, the substrate W illustrated in FIG. 4 was prepared. The substrate W includes the first region R1 that is a silicon oxide film, and the second region R2 that is a photoresist film for EUV exposure. After that, step ST2 was performed on the substrate W by using the plasma processing apparatus 1.

In step ST2, in the plasma processing chamber 10, plasma PL was generated from a processing gas containing WF₆ gas, N₂ gas and CF₄ gas, and the first region R1 was etched with the plasma PL. The processing gas does not contain other gases. The flow rate of the N₂ gas was 250 sccm. The flow rate of the WF₆ gas was lower than the flow rate of the N₂ gas. The flow rate of the CF₄ gas was higher than the flow rate of the WF₆ gas and the flow rate of the N₂ gas.

### Second Experiment

The second experiment was performed in the same manner as in the first experiment except that WF₆ gas was not used in step ST2.

(First Experiment Results)

In each of the first experiment and the second experiment, the etching amount of the first region R1 and the etching amount of the second region R2 were measured, and the etching selectivity of the first region R1 with respect to the second region R2 was calculated. The etching selectivity in the first experiment was 1.45. The etching selectivity in the second experiment was 1.11. Therefore, it can be found that the etching selectivity is improved by the addition of WF₆ gas.

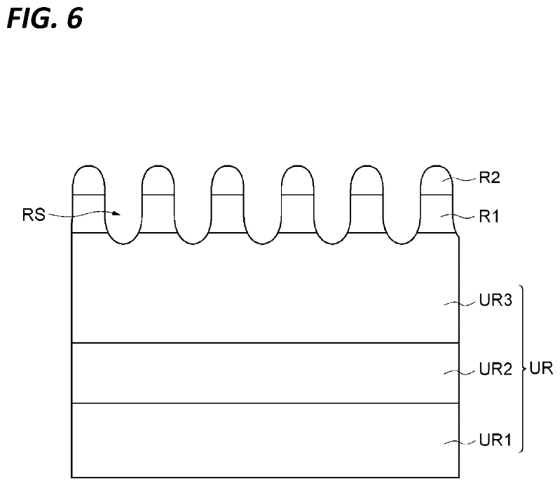

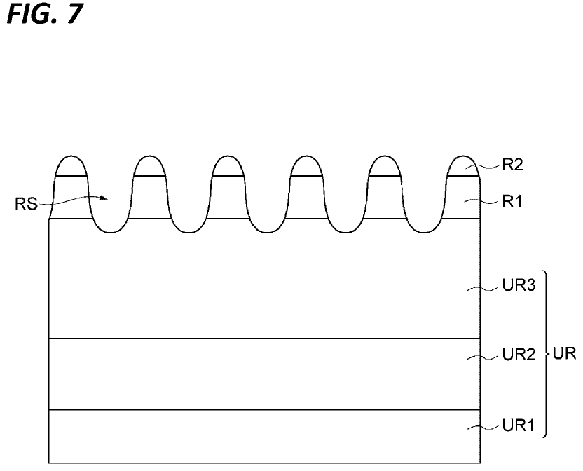

TEM images of the cross sections of the substrates W obtained in the first experiment and the second experiment were observed. FIG. 6 is a view illustrating an example of a TEM image of the cross section of the substrate obtained by executing the etching method in the first experiment. FIG. 7 is a view illustrating an example of a TEM image of the cross section of the substrate obtained by executing the etching method in the second experiment. The side wall of the recess RS formed in the first region R1 in the first experiment had higher verticality than the side wall of the recess RS formed in the first region R1 in the second experiment. Therefore, it can be found that the verticality of the side wall of the recess RS is improved by the addition of WF₆ gas.

### Third Experiment

The third experiment was performed in the same manner as in the first experiment except that in step ST2, the processing gas further contained H₂ gas, and the flow rate of the N₂ gas was different. The flow rate of the H₂ gas was 10 sccm. The flow rate of the N₂ gas was 240 sccm.

### Fourth Experiment

The fourth experiment was performed in the same manner as in the third experiment except that in step ST2, the flow rate of the H₂ gas and the flow rate of the N₂ gas were different. The flow rate of the H₂ gas was 15 sccm. The flow rate of the N₂ gas was 235 sccm.

### Fifth Experiment

The fifth experiment was performed in the same manner as in the third experiment except that in the step ST2, the flow rate of the H₂ gas and the flow rate of the N₂ gas were different. The flow rate of the H₂ gas was 20 sccm. The flow rate of the N₂ gas was 230 sccm.

### Sixth Experiment

The sixth experiment was performed in the same manner as in the third experiment except that in step ST2, the flow rate of the H₂ gas and the flow rate of the N₂ gas were different. The flow rate of the H₂ gas was 25 sccm. The flow rate of the N₂ gas was 225 sccm.

### Seventh Experiment

The seventh experiment was performed in the same manner as in the third experiment except that in step ST2, the flow rate of the H₂ gas and the flow rate of the N₂ gas were different. The flow rate of the H₂ gas was 30 sccm. The flow rate of the N₂ gas was 220 sccm.

### Eighth Experiment

The eighth experiment was performed in the same manner as in the third experiment except that in step ST2, the flow rate of the H₂ gas and the flow rate of the N₂ gas were different. The flow rate of the H₂ gas was 40 sccm. The flow rate of the N₂ gas was 210 sccm.

(Second Experiment Result)

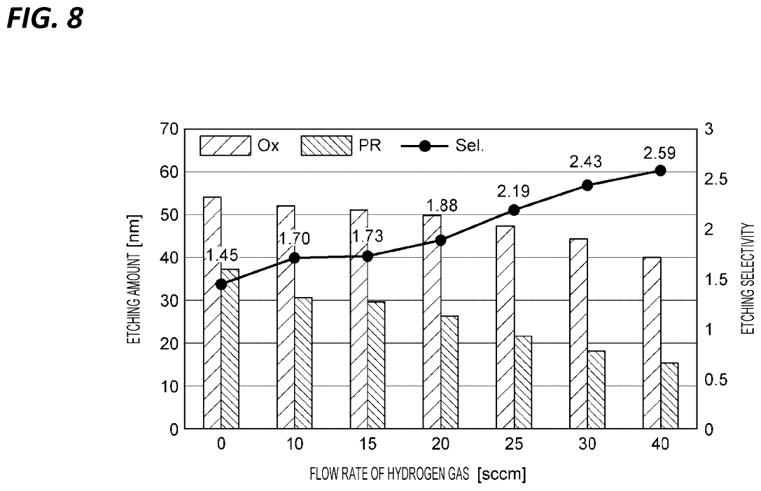

In each of the first experiment, and the third experiment to the eighth experiment, the etching amount of the first region R1 and the etching amount of the second region R2 were measured, and the etching selectivity of the first region R1 with respect to the second region R2 was calculated. The results are illustrated in FIG. 8. FIG. 8 is a graph illustrating an example of the relationship between the flow rate of the hydrogen gas and the etching amount or the etching selectivity. On the graph, “Ox” represents the etching amount of the first region R1. “PR” represents the etching amount of the second region R2. “Sel.” represents the etching selectivity of the first region R1 with respect to the second region R2.

As illustrated in FIG. 8, it can be found that the etching selectivity increases due to the addition of H₂ gas. It can also be found that the etching selectivity increases as the flow rate of H₂ gas increases. Furthermore, it can be found that when the flow rate of the H₂ gas is 25 sccm or more, the etching amount of the first region R1 is reduced.

(Third Experiment Result)

TEM images of the cross sections of the substrates W obtained in the second experiment and the fifth experiment were observed. The side wall of the recess RS formed in the first region R1 in the fifth experiment had higher verticality than the side wall of the recess RS formed in the first region R1 in the second experiment. Therefore, it can be found that the verticality of the side wall of the recess RS is improved by the addition of WF₆ gas and H₂ gas.

Although various embodiments have been described, the present disclosure is not limited to the above-described embodiments, and various additions, omissions, substitutions, and modifications may be made. Further, elements in different embodiments may be combined to form other embodiments.

Here, various embodiments included in the present disclosure will be described in the followings [E1] to [E10].

[E1] An etching method including:
(a) preparing a substrate having a first region including a first material that contains silicon, and a second region including a second material different from the first material, and
(b) etching the first region by plasma generated from a processing gas containing a carbon- and fluorine-containing gas, a nitrogen-containing gas, and a metal halide gas,
in which in (b), a flow rate of the metal halide gas is lower than a flow rate of the carbon- and fluorine-containing gas and a flow rate of the nitrogen-containing gas.

According to the method [E1], the etching selectivity of the first region with respect to the second region may be improved. The mechanism is presumed as follows, but is not limited thereto. In (b), carbon-containing deposits and metal-containing deposits are formed on the second region, so that the etching amount of the second region is reduced.

[E2] The etching method described in [E1], in which the processing gas further contains a hydrogen-containing gas.

In this case, the etching selectivity of the first region with respect to the second region may be further improved. The mechanism is presumed as follows, but is not limited thereto. In (b), deposits containing carbon and hydrogen are formed on the second region. Otherwise, in (b), the metal halide gas is reduced by the hydrogen-containing gas, so that metal deposits are formed on the second region.

[E3] The etching method described in [E1] or [E2], in which the metal halide gas contains at least one metal of tungsten, titanium, molybdenum, vanadium, platinum, hafnium, niobium, tantalum, and rhenium.

[E4] The etching method described in [E3], in which the metal halide gas incudes at least one of tungsten hexafluoride gas, tungsten hexabromide gas, tungsten hexachloride gas, WF₅Cl gas, titanium tetrachloride gas, molybdenum pentafluoride gas, vanadium hexafluoride gas, platinum hexafluoride gas, hafnium tetrafluoride gas, and niobium pentafluoride gas.

[E5] The etching method described in any one of [E1] to [E4], in which the carbon- and fluorine-containing gas includes at least one of fluorocarbon gas and hydrofluorocarbon gas.

[E6] The etching method described in any one of [E1] to [E5], in which the second region is a mask having an opening on the first region.

[E7] The etching method described in any one of [E1] to [E6], in which the second region is a photoresist film.

[E8] The etching method described in [E7], in which the photoresist film is a photoresist film for EUV exposure.

[E9] The etching method described in any one of [E1] to [E8], in which the first region is a silicon oxide film.

[E10] A plasma processing apparatus including:
a chamber,
a substrate support configured to support a substrate in the chamber, the substrate having a first region including a first material that contains silicon, and a second region including a second material different from the first material,
a gas supply unit configured to supply a processing gas containing a carbon- and fluorine-containing gas, a nitrogen-containing gas, and a metal halide gas, into the chamber,
a plasma generation unit configured to generate plasma from the processing gas within the chamber, and
a control unit,
in which the control unit is configured to control the gas supply and the plasma generation unit such that the first region is etched with the plasma, and
the control unit is configured to control the gas supply such that in the etching step of the first region, a flow rate of the metal halide gas is lower than a flow rate of the carbon- and fluorine-containing gas and a flow rate of the nitrogen-containing gas.

According to one embodiment, provided are a substrate processing method and a plasma processing apparatus which may improve the etching selectivity.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
(a) preparing a substrate having a first region including a first material that contains silicon, and a second region including a second material different from the first material; and
(b) etching the first region by plasma generated from a processing gas containing a carbon- and fluorine-containing gas, a nitrogen-containing gas, and a metal halide gas,
wherein in (b), a flow rate of the metal halide gas is lower than a flow rate of the carbon- and fluorine-containing gas and a flow rate of the nitrogen-containing gas.

2. The etching method according to claim 1, wherein the processing gas further contains a hydrogen-containing gas.

3. The etching method according to claim 1, wherein the metal halide gas contains at least one metal of tungsten, titanium, molybdenum, vanadium, platinum, hafnium, niobium, tantalum, and rhenium.

4. The etching method according to claim 3, wherein the metal halide gas includes at least one of tungsten hexafluoride gas, tungsten hexabromide gas, tungsten hexachloride gas, WF₅Cl gas, titanium tetrachloride gas, molybdenum pentafluoride gas, vanadium hexafluoride gas, platinum hexafluoride gas, hafnium tetrafluoride gas, and niobium pentafluoride gas.

5. The etching method according to claim 1, wherein the carbon- and fluorine-containing gas includes at least one of fluorocarbon gas and hydrofluorocarbon gas.

6. The etching method according to claim 1, wherein the second region is a mask having an opening on the first region.

7. The etching method according to claim 1, wherein the second region is a photoresist film.

8. The etching method according to claim 7, wherein the photoresist film is a photoresist film for EUV exposure.

9. The etching method according to claim 1, wherein the first region is a silicon oxide film.

10. A plasma processing apparatus comprising:
a chamber;
a substrate support configured to support a substrate in the chamber;
a gas supply configured to supply a processing gas into the chamber;
a plasma generator configured to generate plasma from the processing gas in the chamber; and
a controller,
wherein the controller is configured to control the gas supply and the plasma generator to execute a process including:
(a) preparing a substrate having a first region including a first material that contains silicon, and a second region including a second material different from the first material; and
(b) etching the first region by plasma generated from a processing gas containing a carbon- and fluorine-containing gas, a nitrogen-containing gas, and a metal halide gas,
wherein in (b), a flow rate of the metal halide gas is lower than a flow rate of the carbon- and fluorine-containing gas and a flow rate of the nitrogen-containing gas.
